(19) United States
(12) Patent Application Publication
(10) Pub. No.: US 2025/0253299 A1
(43) Pub. Date: Aug. 7, 2025

(54) MICROLED DISPLAY WITH INTEGRATED CAMERA

(71) Applicant: Lumileds LLC, San Jose, CA (US)

(72) Inventor: Jeffrey Vincent DiMaria, San Jose, CA (US)

(21) Appl. No.: 18/430,058

(22) Filed: Feb. 1, 2024

(51) Int. Cl. H01L 25/16; H01L 25/075; H01L 27/146

(52) U.S. Cl. CPC H01L 25/167; H01L 25/0753; H10F 39/014; H10F 39/182; H10F 39/184; H10F 39/8027

(57) ABSTRACT

A light emitting diode (LED) display and method of forming the display are disclosed. The display includes microLED pixels disposed on the backplane interspersed with photodetector pixels. Each photodetector pixel contains a metasurface that uses a grating to accept a narrow angular range of light, insulating spacers, and a conductive waveguide layer disposed between the insulating spacers. The insulating spacers have a refractive index to permit coupling to the waveguide layer, which supports surface plasmons and acts as a waveguide for in-plane light. The insulating spacers or another layer is formed from a material whose refractive index changes with at least one of an applied electrical or thermal stimulus to control a direction of a center angle of the narrow angular range.

### BACKGROUND OF THE DISCLOSURE

Light-emitting diodes (LEDs) provide an efficient and relatively smaller source of light compared to conventional light sources. The use of LEDs has evolved from systems that provide purely ambient lighting to more complicated systems, for example those incorporated in portable devices. Due at least in part to wide variety of LED applications, there is ongoing effort to improve LED technology, applications that use LEDs, as well as develop new LED uses.

### BRIEF DESCRIPTION OF THE DRAWINGS

FIG. 1 shows an illumination apparatus, in accordance with some examples.

FIG. 2A illustrates a cross-section of a display, in accordance with some examples.

FIG. 2B illustrates a top view of the display of FIG. 2A, in accordance with some examples.

FIG. 2C illustrates a photodetector of FIG. 2A, in accordance with some examples.

FIG. 3A illustrates a display, in accordance with some examples.

FIG. 3B illustrates a top view of the display of FIG. 3A, in accordance with some examples.

FIG. 4 illustrates a direct view display with eye tracking, according to some embodiments.

FIG. 5A illustrates a direct view display with eye tracking, according to some embodiments.

FIG. 5B illustrates the direct view display of FIG. 5A with the eye in a different location, according to some embodiments.

FIG. 6 shows an example of an electronic device in accordance with some embodiments.

FIG. 7 shows a block diagram of an example of a visualization system that contains the structure described herein.

FIG. 8 show an example method of forming a display, in accordance with some embodiments. Corresponding reference characters indicate corresponding parts throughout the several views. Elements in the drawings are not necessarily drawn to scale. The configurations shown in the drawings are merely examples and should not be construed as limiting in any manner.

### DETAILED DESCRIPTION

The use of the LEDs in electronic devices has increased rapidly as the number and types of devices have expanded in various ways. Beyond mere displays, for example, compact light sources have recently been incorporated in augmented reality (AR) and virtual reality (VR) devices, among others. Such devices may be enabled by arrays of LEDs, and in some cases, specifically microLED arrays.

A microLED array may contain thousands to millions of microscopic microLEDs that may be individually controlled or controlled in groups of pixels (e.g., 5×5 groups of pixels). MicroLEDs are relatively small (e.g., <0.07 mm on a side) and may provide monochromic or multi-chromic light, typically red, green, blue, or yellow using inorganic semiconductor material. Other LEDs may have a size, for example, of about 4 mm², 250 micron×250 micron, or larger. Unless otherwise indicated, discussions of LEDs herein include microLEDs.

Active layers of LEDs in general may be formed from one or more inorganic materials usually either III-V materials (defined by columns of the Periodic Table) or II-VI materials. For example, LEDs may be formed using doped gallium nitride (GaN) or ternary compounds such as aluminum gallium arsenide (AlGaAs), indium gallium nitride (InGaN), or indium gallium phosphide (InGaP) or quaternary compounds such as indium gallium arsenide phosphide (InGaAsP).

LEDs may emit light in the visible spectrum (about 400 nm to about 800 nm) and/or may emit light in the infrared spectrum (above about 800 nm). LEDs may be formed by epitaxially growing active, n- and p-type semiconductors on a rigid substrate (which may be textured). The substrate may include, for example, sapphire aluminum oxide (Al₂O₃) or silicon carbide (SiC), among others. In particular, various layers are deposited and processed on the substrate during fabrication of the LEDs to form a LED array. The surface of the substrate may be pretreated to anneal, etch, polish, etc. the surface prior to deposition of the various semiconductor, dielectric, and conductive layers used to form an LED structure. The original substrate may be removed and replaced by suppporting structure such as a temporary substrate or a relatively thin transparent substrate, such as glass or polyimide. In general, the various active layers may be fabricated using epitaxial semiconductor deposition to provide one or more semiconductor layers, metal deposition (e.g., by sputtering), oxide growth, as well as etching, liftoff, and cleaning, among other operations.

In some aspects, the substrate (original or temporary) may be removed from the LED structure after fabrication and after connection to contacts on a backplane via metal bonding such as wire or ball bonding. The backplane may be a printed circuit board or wafer containing integrated circuits (ICs), such as a complementary metal oxide semiconductor (CMOS) IC wafer.

The semiconductor deposition operations may be used to create an active region of the LED in which electron-hole recombination occurs and the light from the LED is generated. The active region may be, for example, one or more quantum wells. Metal contacts may be used to drive provide current to the n- and p-type semiconductors from the ICs of the backplane on which the LED array is disposed. Methods of depositing materials, layers, and thin films may include, for example: sputter deposition, atomic layer deposition (ALD), chemical vapor deposition (CVD), physical vapor deposition (PVD), plasma enhanced atomic layer deposition (PEALD), plasma enhanced chemical vapor deposition (PECVD), and combinations thereof, among others.

In some aspects, one or more other layers, such as a phosphor-converting layer that contains phosphor particles, may be disposed on some or all of the LEDs or across the LED array to convert at least a portion of the light from the LEDs to light of a different wavelength. For example, blue light may be converted into near infrared light or white light by the phosphor-converting layer. In other embodiments, one or more optics such as lenses or reflectors (at the wavelength emitted by the active region) may be disposed on some or all of the LEDs or across the LED array to adjust the light from the LEDs.

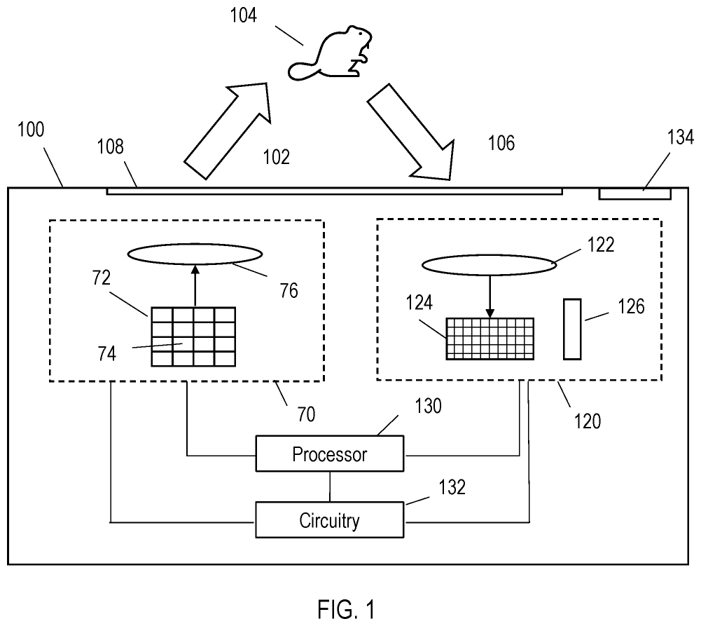

FIG. 1 shows an illumination apparatus 100, in accordance with some examples. The illumination apparatus 100 may be, for example, a smart phone or standalone camera that contains a light source 110 such as that described herein. The illumination apparatus 100 may also include a camera 120 that captures an image of a scene 104 during an exposure duration of the camera 120, whether or not the scene 104 is illuminated by the light source 110. A processor 130 may be used to control various functions of the illumination apparatus 100, including activation of the light source 110 and the camera 120 in addition to whether or not a shutter, disposed in an opening 108 of a housing of the illumination apparatus 100, is open.

The opening 108 may be a single opening as shown in FIG. 1 or may include multiple separate openings. Similarly, the shutter may be a single shutter that covers both the light source 110 and the camera 120 or may include multiple separate shutters that covers only one of the light source 110 or the camera 120 and are individually controllable by the processor 130.

The light source 110 may include one or more LED arrays 112 on a complementary metal oxide semiconductor (CMOS) or silicon (Si) backplane, for example. Each of the one or more LED arrays 112 may include multiple LEDs 114 that may produce visible and/or infrared light during at least a portion of the exposure duration of the camera 120. The LEDs 114 may be microLEDs and the LED arrays 112 may be microLED arrays. Each LED 114 or set of LEDs (e.g., red, green, blue LED) may form a pixel of the corresponding LED array 112.

LEDs 114 in a particular LED array 112 that emit light in the infrared spectrum may be, for example, interspersed with LEDs 114 that emit light in the visible spectrum, or each type of LED (visible emitter/infrared emitter) may be disposed on different sections of the particular LED array 112. Alternatively, each LED array 112 may only emit light in either the visible spectrum or the infrared spectrum; separate (one or more) LED arrays may be used to emit light in the infrared spectrum. Each of the individual LED arrays 112, LEDs 114 within each LED array 112, and/or groups of LEDs 114 within each LED array 114 (e.g., sets of 3×3 LEDs) may be individually controllable by the processor 130.

The light source 110 may include at least one lens 116 and/or other optical elements such as reflectors. The lens 116 and/or other optical elements may direct the light emitted by the one or more LED arrays 112 toward the scene 104 as illumination 102. In particular, due to the height-to-area ratio of microLEDs, reflectors may be disposed between adjacent pixels in the LED array 112 or at the edges of the LED array 112 to increase the light-extraction efficiency and provide beam shaping.

The camera 120 may sense light at at least the wavelength or wavelengths emitted by the one or more LED arrays 112. Similar to the light source 110, the camera 120 may include optics (e.g., at least one camera lens 122) that are able to collect reflected light 106 of the illumination 102 that is reflected from and/or emitted by the scene 104. The camera lens 122 may direct the reflected light 106 onto a light sensor 124 to form an image of the scene 104 on the light sensor 124. The light sensor 124 may contain multiple pixels to have a desired resolution (e.g., each pixel may correspond to a different LED 114). In some embodiments, the light sensor 124 may also be disposed on the CMOS or Si backplane.

The processor 130 may control and drive the LEDs 114 in the one or more LED arrays 112 via circuitry 132 that includes one or more drivers. For example, the processor 130 may optionally control one or more LEDs 114 in the one or more LED arrays 112 independent of another one or more LEDs 114 in the one or more LED arrays 112, so as to illuminate the scene in a specified manner. The processor 130 may also receive a data signal that represents the image of the scene 104 and process the signal to adjust driving of the LEDs 114 or otherwise adjust the image as desired.

In addition, one or more detectors 126 may be incorporated in the camera 120. In other embodiments, instead of being incorporated in the camera 120, the one or more detectors 126 may be incorporated in one or more different areas, such as the light source 110 or elsewhere close to the camera 120. The one or more detectors 126 may include multiple different sensors to sense visible and/or infrared light (e.g., from the scene 104), ambient light and/or variations/flicker in the ambient light in addition to reception of the reflected light from the LEDs 114, or other actions, such as physical movement of the illumination apparatus 100.

The light sensor 124 of the camera 120 may be of higher resolution than the sensors of the one or more detectors 126 to obtain an image of the scene with a desired resolution. The sensors of the one or more detectors 126 may have one or more segments (that are able to sense the same wavelength/range of wavelengths or different wavelength/range of wavelengths), similar to the LED arrays 112. In some embodiments, if multiple detectors are used, one or more of the detectors may detect visible wavelengths and one or more of the detectors may detect infrared wavelengths; like the one or more LED arrays 112, the one or more detectors 126 may be individually controllable by the processor 130.

In some embodiments, instead of, or in addition to, being provided in the camera 120, one or more of the sensors of the one or more detectors 126 may be provided in the light source 110. In some embodiments, the light source 110 and the camera 120 may be integrated in a single module, while in other embodiments, the light source 110 and the camera 120 may be separate modules that are disposed on a PCB. In other embodiments, the light source 110 and the camera 120 may be attached to different PCBs—for example, as the camera 120 may be thicker than the light source 110, which may result in design issues if the light source 110 and the camera 120 are attached to the same PCB. In the latter embodiment, multiple openings may be present in the housing at least one of which may be eliminated with the use of an integrated light source 110 and camera 120.

The LEDs 114 may be driven using a direct current (DC) driver or pulse width modulation (PWM) in the circuitry 132. Using DC driving may encounter color differences if the segmented one or more LED arrays 112 is driven at different current densities, while PWM driving may generate artifacts due to ambient lighting conditions. The flicker sensor, if present, may sense the variation of artificial lighting at the wall current frequency or electronic ballasts frequencies (e.g., 50 Hz or 60 Hz or an integral multiple thereof), in addition to the phase of the flicker. The camera sensor is then tuned to an integration time of an integral multiple of the time period (1/f) or triggered at the phase where the illumination changes most slowly (minimum or maximum intensity, with the maximum intensity preferred for signal-to-noise ratio considerations). The LEDs 114 may be driven using a PWM whose phase shift varies between LEDs 114 to reduce potential current surge issues. As shown, the circuitry 132 may include one or more drivers used to drive the LEDs 114 in the one or more LED arrays 112, as well as other components, such as the actuators.

The illumination apparatus 100 may also include an input device 134, for example, a user-activated input device such as a button that is depressed to take a picture. The light source 110 and camera 120 may be disposed in a single housing.

As above, the light source 110 of FIG. 1 may contain individually addressable LED segments to allow selective illumination of the scene 104. For array sizes larger than 3×3 matrices, the LED segments may be combined with an integrated driver to allow the function of individual addressability and obtain the small form factor desired for mobile devices without creating issues in layout of the semiconductor layers used to create the integrated devices. LEDs can be used in the illumination apparatus 100 shown in FIG. 1 to form different types of displays (e.g., smart phone displays, computer displays, smart watches, monitors, and TVs) and light engines including adaptive automotive headlights, AR, VR, or mixed-reality (MR) headsets, smart glasses, et al. The individual LED pixels in these architectures may have an area of few square millimeters down to few square micrometers depending on the matrix or display size and pixel-per-inch requirements.

As above, information displays such as mobile phones and computer monitors that are used for video conferencing or that use video functionality also include a camera assembly. In some instances, such functionality may be represented as a CMOS camera on a bezel, a hole in the display, or “notch/island” as in a product that includes the camera. In commercial products incorporating a CMOS photodetector array, the camera lens aperture disrupts the visual appearance of the display (e.g. appears as a dark dot, notch, or island where nothing can be displayed) or is offset from the display, which has negative aesthetic effects during video conferencing. Moreover, in the latter application, a person viewing the video is not looking directly into the camera and appears to be looking off to the side from the perspective of the person with whom the person is speaking.

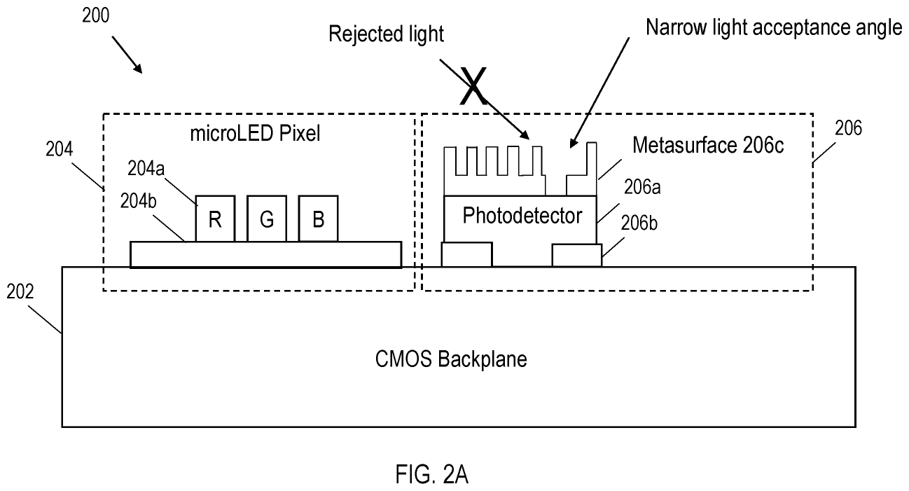

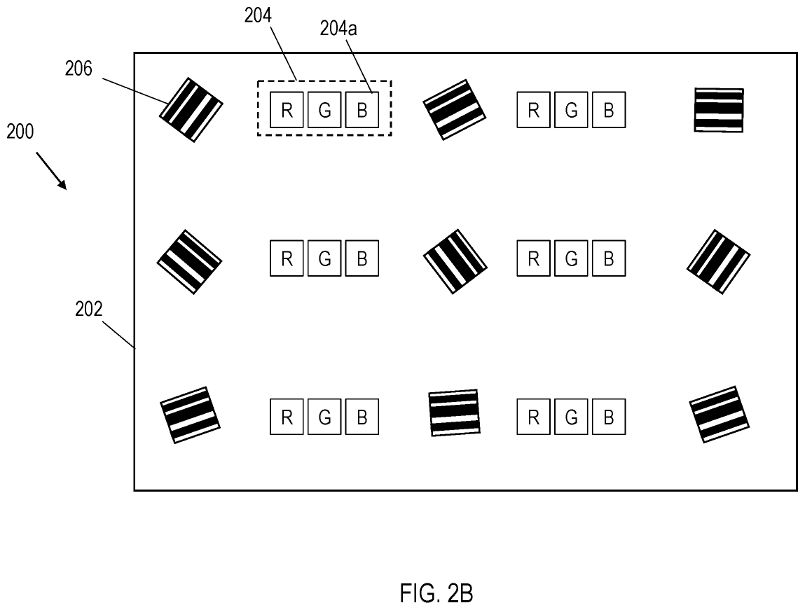

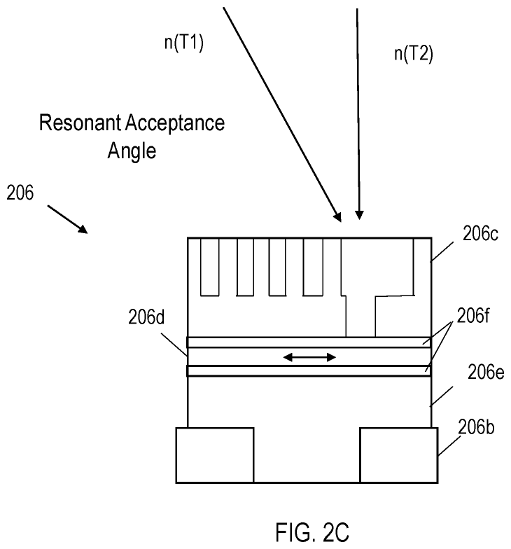

Embedding the CMOS photodetector array into the display removes undesired elements of the user experience due to the display/camera configuration. Such an arrangement is shown in FIG. 2A, which illustrates a cross-section of a display, in accordance with some examples. In the display 200 of FIG. 2A, the direct-view microLED pixels 204 in a microLED array may be small enough in these applications to integrate photodetector pixels 206 between the microLED pixels 204 on a CMOS backplane 202. Each microLED pixel 204 may include red, green, or blue microLEDs 204a, for example, and a support 204b that contains electrodes and circuitry through which individual activation of the microLEDs 204a is achieved. Such an arrangement may provide substantially identical optical paths for the emitter (microLED array) and receiver (photodetector array), while filling gaps between sets of microLED pixels 204 using the photodetector pixels 206 to embed functionality that is integrated onto the CMOS backplane 202. While in some embodiments, each photodetector pixel 206 may correspond to a corresponding microLED pixel 204, in other embodiments this may not be the case—a photodetector pixel 206 may be disposed between every other set of adjacent microLED pixels 204 for example. In the former case, each photodetector pixel 206 is disposed between adjacent microLED pixels 204 and each microLED pixel 204 is disposed between adjacent photodetector pixels 206 (this notably excludes any edge pixel). The relative number of photodetector pixels 206 to microLED pixels 204 may depend on the imaging requirements of the application in which the photodetector pixels 206 are used.

In this case however, the microLED array may still use an optical system to reject and focus background light to generate an image of the scene. To this end, the photodetector pixel 206 may contain a metasurface 206c provided on a photodetector structure 206a to which contact is made via electrodes 206b through which signals generated by light impinging on the photodetector structure 206a are supplied to the CMOS backplane 202. The photodetector pixel 206 is thus integrated with the microLED array, where the photodetector pixels 206 of the CMOS photodetector array are distributed between the microLED pixels 204 of the microLED array.

In particular, as shown in FIG. 2A, optical element (filter) formed by the metasurface 206c may be used to reject background illumination and form an image when the photodetector pixel 206 of the CMOS photodetector array is embedded with a microLED display. Thus, as shown in FIG. 2A, there is a narrow angular range in k-space through which light of a particular wavelength impinging on the photodetector pixel 206 (corresponding to light from the microLED array or adjacent microLED pixels) is coupled the metasurface 206c; light from outside the small acceptance angular range may be rejected. The metasurface 206c provides unidirectional coupling of the impinging light.

As shown in FIG. 2C, the photodetector pixel 206 may include the metasurface 206c, which may be a grating that provides the filtering of the received light (depending on the grating period), and a waveguide layer 206d formed from a conductor disposed on a substrate 206e. The waveguide layer 206d may support surface plasmons and acts as a waveguide for in-plane light (essentially perpendicular to the top surface of the photodetector pixel 206). Insulating spacers 206f, formed from SiOx for example, may be provided on opposing sides of the waveguide layer 206d and the metasurface 206c may be formed on one of the insulating spacers 206f. The insulating spacers 206f may be used to match the refractive index to the metasurface 206c and substrate 206e to allow coupling between lateral sections of the photodetector pixel 206. The light in the waveguide layer 206d may be guided to an active region of the photodetector pixel 206, where the light is used to generate current that is sensed by the processor.

The photodetector pixel 206 may have further include a thermally or electrooptically sensitive material layer (such as Vanadium Oxide or liquid crystal) integrated into the diffractive array formed by the metasurface 206c. The electrooptically sensitive material layer may be a separate layer (e.g., disposed between the metasurface 206c and the insulating spacers 206f) or may be one or both of the insulating spacers 206f. This permits control of the refractive index of the material layer in response to application of an external stimulus, such as heat or electric current. Since the in-plane wavevector of allowed surface plasmon polariton (SPP) modes propagating in the waveguide layer 206d depend on the refractive index of the surrounding environment (including the insulating spacers 206f), and because the momentum supplied by the grating of the metasurface 206c is fixed due to the fixed geometry of the structure of the metasurface 206c, then the acceptance angle of light impinging on the photodetector pixel 206 (i.e., light of different in-plane and out-of-plane momentum) may be varied by varying the refractive index and dispersion of the structure. This may be controlled by the processor to tune the field-of-view to focus the response to a particular direction (e.g., to a viewer of the display).

In some embodiments, the metasurface 206c may be used instead of one or more lens (each having a single optical axis). This may permit the photodetector pixels 206 to be distributed across and between the microLED pixels. The metasurface 206c may be further designed to reject specific polarizations. In this case, different photodetector pixels 206 may be used to detect each polarization, each color, and each minimum resolution angle; that is, each photodetector pixel 206 may be configured to detect light having a specific set of parameters that include polarization, color, and angular range. Thus, more than one photodetector pixel 206 may be disposed between adjacent microLED pixels 204, with each photodetector pixel 206 configured to detect light having at least one different parameter, or photodetector pixels 206 configured to detect light of at least one different parameter may be disposed between different adjacent microLED pixels 204). The photodetector pixel 206 may also have one or more color filters applied to a top surface of the metasurface 206c to allow transmittance of red, green, blue light onto the photodetector pixel 206.

In other embodiments, the photodetector array may be disposed adjacent to the microLED array rather than the photodetector pixels being disposed between the microLED pixels.

Further, the use of reflectors (not shown in FIG. 2A) between the individual microLED pixels 204 may reduce the optical cross-talk between the microLED pixels 204, as well as between the microLED pixels 204 and the photodetector pixels 206 of the CMOS photodetector array.

At least some of the microLEDs 204a may share a common electrode (anode or cathode). To integrate the microLED array and the CMOS photodetector array, the microLEDs 204a and photodetector pixels 206 may share at least some circuitry, such as the common electrode 206b.

In some embodiments, the microLED pixels 204 may be transferred directly onto the CMOS backplane 202 with thermocompression bonding (i.e., via mass transfer). Afterwards (or before), the photodetector pixels 206 may be similarly transferred onto the CMOS backplane 202 via mass transfer. The gap between adjacent microLED pixels 204 may be on the order of 100 microns.

FIG. 2B illustrates a top view of the display of FIG. 2A, in accordance with some examples. As shown, the photodetector pixels 206 may be oriented in different directions on the CMOS backplane 202 to accept light from different angles. In some embodiments, the directions may be randomly oriented throughout the display 200. Because the angle of acceptance is relatively narrow (e.g., a full width half maximum between about 10 degrees to about 20 degrees), the variation in orientation of the photodetector pixels 206 may permit rejection by the metasurfaces 206c of light in different locations on the CMOS backplane 202, permitting localization of the image via processing of the signals from the photodetector pixels 206 (and ensuring some light capture from at least some of the image illuminated by the microLED pixels 204 no matter how the display 200 is oriented). In other embodiments, sets of the photodetector pixels 206 may have identical orientations, which are different from the orientation of different sets of the photodetector pixels 206 may have the same orientation. The latter may be more suited to the mass transfer process to create the display 200 as sets of the photodetector pixels 206 by simultaneously transferring to a subsection of the display 200 sets of the photodetector pixels 206 that have the same orientation before moving to the next subsection and transferring another set of the photodetector pixels 206 with a different orientation. In other embodiments, the photodetector pixels 206 may have the same orientation due to the mass transfer process. Thus, the display 200 shown in FIGS. 2A and 2B may be a smartphone screen, for example.

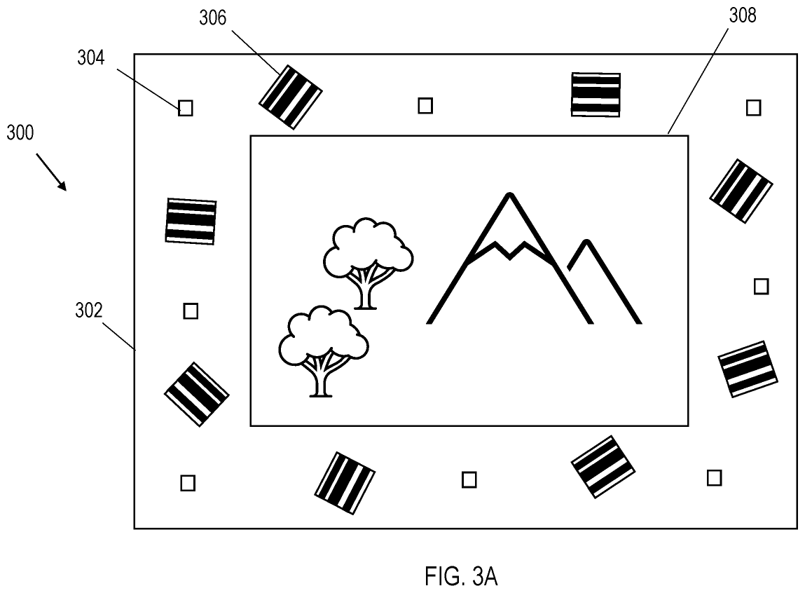

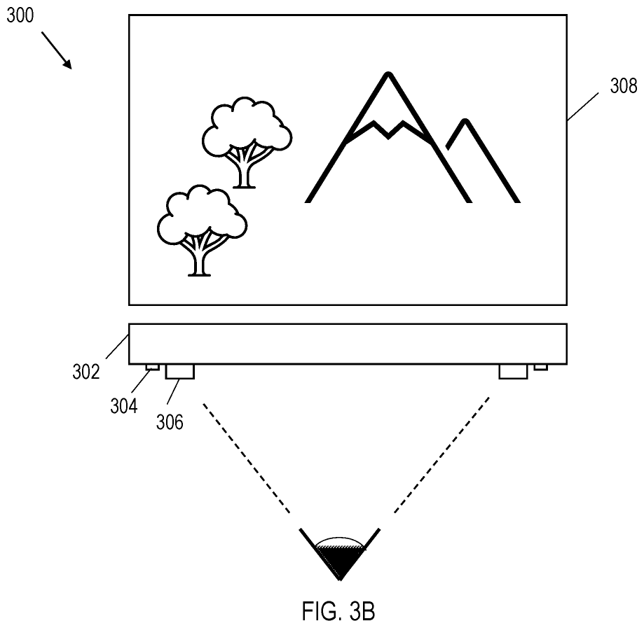

FIG. 3A illustrates a display, in accordance with some examples; FIG. 3B illustrates a top view of the display of FIG. 3A, in accordance with some examples. In the display 300 of FIG. 3A and FIG. 3B, microLED pixels 304 interspersed with photodetector pixels 306 may be embedded in the frame 302 of the display 300. The frame 302 is disposed around a viewing area 308 in which one or more images are displayed. The microLED pixels 304 may emit infrared light that is detected by the photodetector pixels 306 for eye tracking. The infrared light may be in the near-infrared spectrum (about 800 nm to about 2500 nm). The viewing area 308 may contain a substrate with an embedded microLED array that emit visible light. In this case, the microLED pixels 304 may emit infrared light to uniformly illuminate the eye. The image in the viewing area 308 may adjust the image displayed therein based on the eye tracking information obtained from the photodetector pixels 306. In some embodiments, the microLED array embedded in the viewing area 308 may be a sparse microLED array disposed on a transparent substrate that is sufficiently sparse to enable viewing through the viewing area 308. The sparse microLED array may be controlled by a processor in the frame 302 to display AR or VR images or, when determined by a user or automatically by the processor, turned off to be transparent and allow the user to see through the viewing area 308. In other embodiments, rather than using a transparent display, a transparent optical element such as a waveguide plate may be used as the viewing area 308.

A sparse array may be defined as an array in which the surface area of the array is less, or significantly less, than a total surface area of the backplane. For example, a fill factor of the array (e.g., a ratio of occupied surface area to full surface area) can be less than or equal to a specified threshold, such as 10%, 5%, 4%, 3%, 2%, 1%, or another suitable threshold. For example, in a rectangular array with center-to-center spacing along one dimension denoted by spacing x and an occupied area sized along the one dimension by size s, the ratio of s divided by x may be less than or equal to 0.1. In an orthogonal dimension, a similar ratio applies, with the linear size of occupied area being less than or equal to one-tenth the linear center-to-center spacing of the pixels. Combining the two linear dimensions, the occupied surface area is less than or equal to 1% of the surface area of the backplane. Similarly, electrical traces deposited on the transparent flexible substrate to electrically power (e.g., carry current to and from) the devices in each array. In some examples, the electrical traces may be metal traces that are narrow enough to be invisible under typical viewing conditions. In some examples the electrical traces may be formed from one or more transparent electrically conductive materials, such as indium tin oxide (ITO). Because the sparse array of devices and corresponding electrical traces and circuitry has a relatively small fill factor, most of the surface area is substantially transparent as light incident thereon mostly passes through the arrays, with only a relatively small fraction being blocked by the occupied areas and electrical traces.

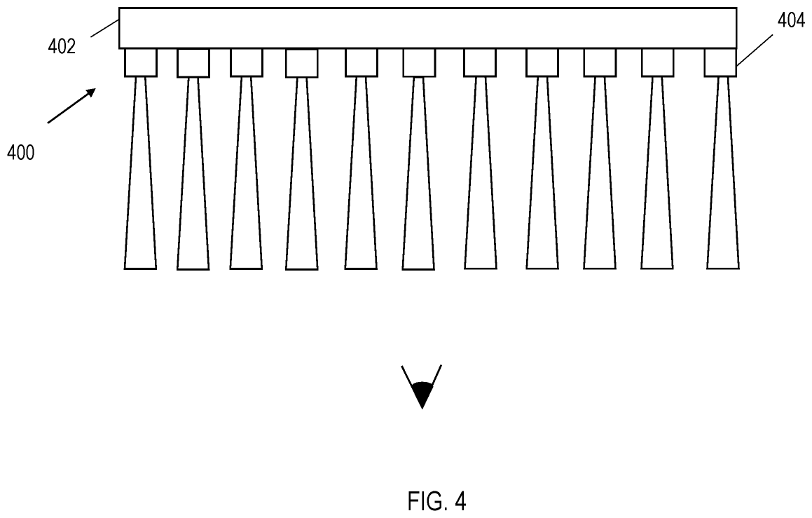

FIG. 4 illustrates a direct view display with eye tracking, according to some embodiments. The display 400 may contain a transparent substrate 402 (e.g. glass) on which arrays 404 of emitters and photodetectors (containing the metasurface) are disposed. The pixels of the display 400 are distributed such that the photodetectors distributed throughout the display 400 are designed to capture a uniform angle of infrared light, emitted by at least some of the emitters, reflected from the eye of a viewer. As photodetector array is larger than the eye, the angular response of the photodetectors may be identical (e.g., a narrow acceptance cone around normal to the transparent substrate 402) thereby permitting direct imaging of the eye or viewer, which is directly in front of the screen formed by the transparent substrate 402.

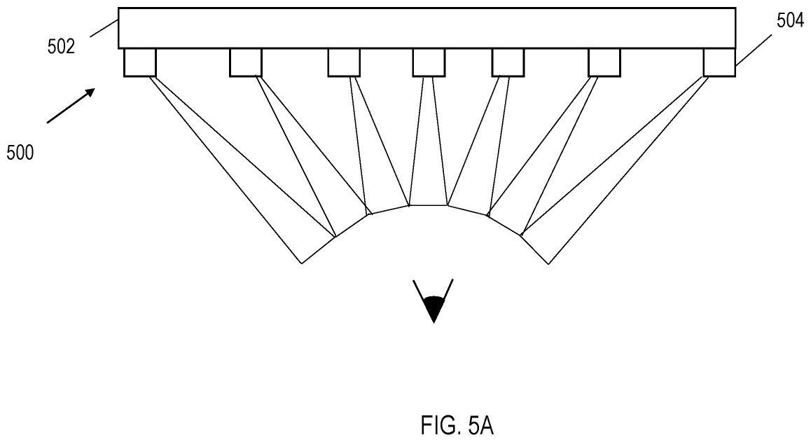

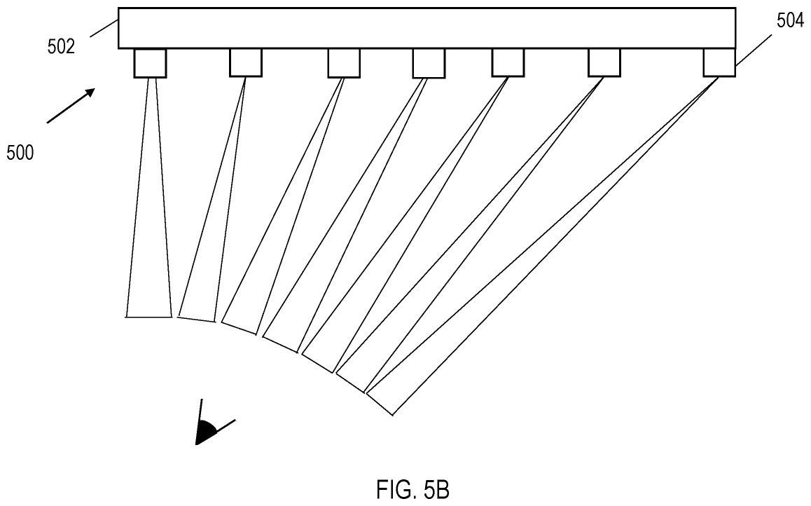

FIG. 5A illustrates a direct view display with eye tracking, according to some embodiments. FIG. 5B illustrates the direct view display of FIG. 5A with the eye in a different location, according to some embodiments. The display 500 may contain a transparent substrate 502 on which arrays 504 of emitters and photodetectors that contain the metasurface are disposed. The pixels of the display 500 are distributed such that the photodetectors distributed throughout the display 500 are designed to capture different angles of infrared light, emitted by at least some of the emitters, reflected from the eye of a viewer. The embodiments of FIGS. 5A and 5B may be used to provide a 3D image due to the pixels of the display 500 being distributed as shown as the various pixels in different locations may image different images onto different eyes of the viewer. This may permit, for example, creation of a 3D avatar to interact with other avatars during a video call.

Thus, the arrangements shown in FIGS. 3A-5B provide examples of AR/VR eye-tracking applications and direct-view display applications. For example, the microLEDs and photodetector pixels containing metasurfaces may be located on the same transparent optical element proximate to the eye of the viewer. The size of the microLEDs and photodetector pixels is small enough so that the structure is effectively transparent. The optical filter formed by the metasurface may be optimized for near infrared wavelengths, thereby enabling a thin form-factor for the eye-tracking imaging element which would otherwise be a separate CMOS camera and optical assembly in an AR or VR headset. Using the metasurface permits the pixel array to avoid having different angular responses; that is each pixel may have a narrow angular response at a predetermined fixed angle (e.g., normal incidence). The pixel array resolution then corresponds to the spatial resolution of the object being imaged (i.e., the eye). The resolution of the microLED array may in some embodiments correspond to the imaging resolution provided by the photodetector pixels.

The direct-view display applications, such as computer monitors, may use photodiode pixels in which the metasurfaces have an identical design, accepting only angles that are near to normal incidence (i.e., within about 5 degrees of normal). The image formed by such a system acts as if imaging objects are placed at infinity. The spatial resolution of the camera that uses the photodiode pixels then corresponds to the pixel pitch and may only image objects directly in front of the display.

In another direct-view display application, for example 3D video conferencing, different angles of the same object at a focal point may be desired. In this case, the distributed photodetector pixels with the metasurface angular filters may be arranged to produce a 3D image of the object at the desired focal point.

Independent of the type of display, the microLED array and photodetector array may be calibrated using the processor. This may include, in the latter case, determining the center angle of acceptance of each photodetector pixel and application of current/heat to adjust the center angle by a predetermined angle. The current/heat may be provided by a separate layer within the photodetector pixel or by direct contact to the thermally/electrooptically sensitive material layer. The correspondence between parameter change and angle change determined during calibration may be stored in a table in memory that is accessed by the processor during operation in the field.

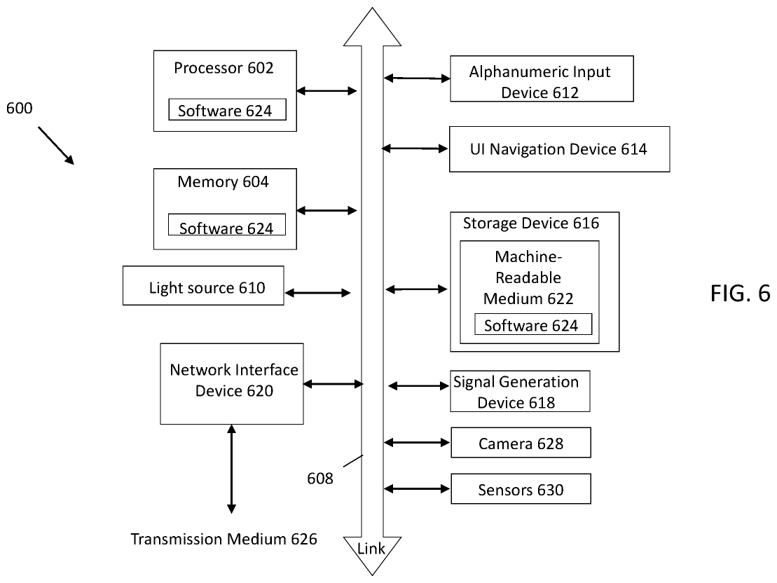

FIG. 6 illustrates an example of an electronic device in accordance with some embodiments. The electronic device 600 may be, for example, a display, a monitor or screen, a wearable/mobile display device such as an AR/VR headset, a vehicular headlight, lighting for a particular area, or any other lighting arrangement. Various elements may be provided on a backplane indicated above, while other elements may be local or remote. Examples, as described herein, may include, or may operate on, logic or a number of components, modules, or mechanisms.

Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The electronic device 600 may include a hardware processor (or equivalently processing circuitry) 602 (e.g., a central processing unit (CPU), a GPU, a hardware processor core, or any combination thereof), a memory 604 (which may include main and static memory), some or all of which may communicate with each other via an interlink (e.g., bus) 608. The memory 604 may contain any or all of removable storage and non-removable storage, volatile memory or non-volatile memory. The electronic device 600 may further include a light source 610 such as the microLEDs described above, or a video display, an alphanumeric input device 612 (e.g., a keyboard), and a user interface (UI) navigation device 614 (e.g., a mouse). In an example, the light source 610, input device 612 and UI navigation device 614 may be a touch screen display. The electronic device 600 may additionally include a storage device (e.g., drive unit) 616, a signal generation device 618 (e.g., a speaker), a network interface device 620, one or more cameras 628, and one or more sensors 630, such as a global positioning system (GPS) sensor, compass, accelerometer, or other sensor such as those described herein. The electronic device 600 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). Some of the elements, such as one or more of the sparse arrays that provide the light source 610 may be remote from other elements and may be controlled by the hardware processor 602.

The storage device 616 may include a non-transitory machine readable medium 622 (hereinafter simply referred to as machine readable medium) on which is stored one or more sets of data structures or instructions 624 (e.g., software) embodying or utilized by any one or more of the techniques or functions described herein. A storage device 616 that includes the non-transitory machine readable medium should not be construed as that either the device or the machine-readable medium is itself incapable of having physical movement. The instructions 624 may also reside, completely or at least partially, within the memory 604 and/or within the hardware processor 602 during execution thereof by the electronic device 600. While the machine readable medium 622 is illustrated as a single medium, the term “machine readable medium” may include a single medium or multiple media (e.g., a centralized or distributed database, and/or associated caches and servers) configured to store the one or more instructions 624.

The term “machine readable medium” may include any medium that is capable of storing, encoding, or carrying instructions for execution by the electronic device 600 and that cause the electronic device 600 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 624 may further be transmitted or received over a communications network using a transmission medium 626 via the network interface device 620 utilizing any one of a number of wireless local area network (WLAN) transfer protocols or a SPI or CAN bus. Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 602.11 family of standards known as Wi-Fi, IEEE 602.14 family of standards known as WiMax, IEEE 602.14.4 family of standards, a Long Term Evolution (LTE) family of standards, a Universal Mobile Telecommunications System (UMTS) family of standards, peer-to-peer (P2P) networks, a next generation (NG)/6^{th} generation (6G) standards among others. In an example, the network interface device 620 may include one or more physical jacks (e.g., Ethernet, coaxial, or phone jacks) or one or more antennas to connect to the transmission medium 626.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical CPU, a single- or multi-core processor, and/or any other device capable of executing or otherwise operating computer-executable instructions, such as program code, software modules, and/or functional processes.

The camera 628 may sense light at least the wavelength or wavelengths emitted by the microLEDs. The camera 628 may include optical elements (e.g., at least one camera lens) that are able to collect reflected light of illumination that is reflected from and/or emitted by an illuminated region. The camera lens may direct the reflected light onto a multi-pixel sensor (also referred to as a light sensor) to form an image of on the multi-pixel sensor.

The processor 602 may control and drive the LEDs via one or more drivers. For example, the processor 602 may optionally control one or more microLEDs in microLED arrays independent of another one or more microLEDs in the microLED arrays, so as to illuminate an area in a specified manner.

In addition, the sensors 630 may be incorporated in the camera 628 and/or the light source 610. The sensors 630 may sense visible and/or infrared light and may further sense the ambient light and/or variations/flicker in the ambient light in addition to reception of the reflected light from the LEDs. The sensors may have one or more segments (that are able to sense the same wavelength/range of wavelengths or different wavelength/range of wavelengths), similar to the LED arrays.

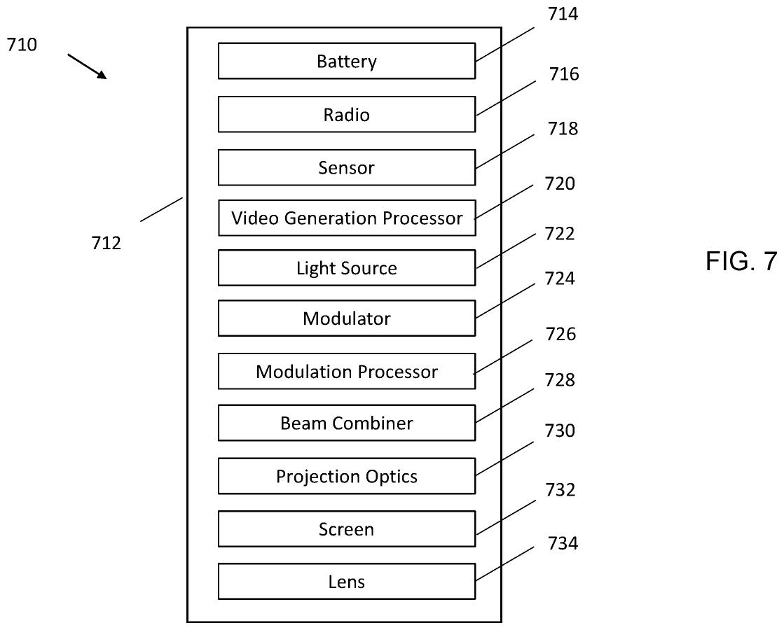

FIG. 7 shows a block diagram of an example of a visualization system that contains the structure described herein. The visualization system 710 can include a wearable housing 712, such as a headset or goggles. The housing 712 can mechanically support and house the elements detailed below. In some examples, one or more of the elements detailed below can be included in one or more additional housings that can be separate from the wearable housing 712 and couplable to the wearable housing 712 wirelessly and/or via a wired connection. For example, a separate housing can reduce the weight of wearable goggles, such as by including batteries, radios, and other elements. The housing 712 can include one or more batteries 714, which can electrically power any or all of the elements detailed below. The housing 712 can include circuitry that can electrically couple to an external power supply, such as a wall outlet, to recharge the batteries 714. The housing 712 can include one or more radios 716 to communicate wirelessly with a server or network via a suitable protocol, such as WiFi.

The visualization system 710 can include one or more sensors 718, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 718 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 718 can capture a real-time video image of the surroundings proximate a user.

The visualization system 710 can include one or more video generation processors 720. The one or more video generation processors 720 may receive scene data from a server and/or a storage medium. The scene data may represent a three-dimensional scene, such as a set of position coordinates for objects in the scene or a depth map of the scene. The one or more video generation processors 720 can receive one or more sensor signals from the one or more sensors 718. In response to the scene data, which represents the surroundings, and at least one sensor signal, which represents the location and/or orientation of the user with respect to the surroundings, the one or more video generation processors 720 can generate at least one video signal that corresponds to a view of the scene. In some examples, the one or more video generation processors 720 can generate two video signals, one for each eye of the user, that represent a view of the scene from a point of view of the left eye and the right eye of the user, respectively. In some examples, the one or more video generation processors 720 can generate more than two video signals and combine the video signals to provide one video signal for both eyes, two video signals for the two eyes, or other combinations.

The visualization system 710 can include one or more light sources 722 such as those described herein that can provide light for a display of the visualization system 710. Suitable light sources 722 can include microLEDs as indicated above in addition to or instead of monolithic LEDs, one or more microLED arrays disposed on a common substrate, segmented microLEDs disposed on a single substrate whose microLEDs are individually addressable and controllable (and/or controllable in groups and/or subsets), and others. In some examples, one or more of the light sources 722 can include microLEDs disposed on a transparent flexible substrate, and a rigid substrate adhered to the transparent flexible substrate with an adhesive layer such that the microLEDs are located between the rigid substrate and the transparent flexible substrate.

The one or more light sources 722 can include light-producing elements having different colors or wavelengths. For example, a light source can include red microLEDs that can emit red light, green microLEDs that can emit green light, and blue microLEDs that can emit blue right. The red, green, and blue light combine in specified ratios to produce any suitable color that is visually perceptible in a visible portion of the electromagnetic spectrum.

The visualization system 710 can include one or more modulators 724. The modulators 724 can be implemented in one of at least two configurations.

In a first configuration, the modulators 724 can include circuitry that can modulate the light sources 722 directly. For example, the light sources 722 can include an array of light-emitting diodes, and the modulators 724 can directly modulate the electrical power, electrical voltage, and/or electrical current directed to each light-emitting diode in the array to form modulated light. The modulation can be performed in an analog manner and/or a digital manner. In some examples, the light sources 722 can include an array of red microLEDs, an array of green microLEDs, and an array of blue microLEDs, and the modulators 724 can directly modulate the red microLEDs, the green microLEDs, and the blue microLEDs to form the modulated light to produce a specified image.

In a second configuration, the modulators 724 can include a modulation panel, such as a liquid crystal panel. The light sources 722 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 724 can include multiple modulation panels that can modulate different colors of light. For example, the modulators 724 can include a red modulation panel that can attenuate red light from a red light source such as a red microLED, a green modulation panel that can attenuate green light from a green light source such as a green microLED, and a blue modulation panel that can attenuate blue light from a blue light source such as a blue microLED.

In some examples of the second configuration, the modulators 724 can receive uniform white light or nearly uniform white light from a white light source, such as a white-light microLED. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 710 can include one or more modulation processors 726, which can receive a video signal, such as from the one or more video generation processors 720, and, in response, can produce an electrical modulation signal. For configurations in which the modulators 724 directly modulate the light sources 722, the electrical modulation signal can drive the light sources 722. For configurations in which the modulators 724 include a modulation panel, the electrical modulation signal can drive the modulation panel.

The visualization system 710 can include one or more beam combiners 728 (also referred to as beam splitters), which can combine light beams of different colors to form a single multi-color beam. For configurations in which the light sources 722 can include multiple microLEDs of different colors, the visualization system 710 can include one or more wavelength-sensitive (e.g., dichroic) beam combiners 728 that can combine the light of different colors to form a single multi-color beam.

The visualization system 710 can direct the modulated light toward the eyes of the viewer in one of at least two configurations. In a first configuration, the visualization system 710 can function as a projector, and can include suitable projection optics 730 that can project the modulated light onto one or more screens 732. The screens 732 can be located a suitable distance from an eye of the user. The visualization system 710 can optionally include one or more lenses 734 that can locate a virtual image of a screen 732 at a suitable distance from the eye, such as a close-focus distance, such as 500 mm, 950 mm, or another suitable distance. In some examples, the visualization system 710 can include a single screen 732, such that the modulated light can be directed toward both eyes of the user. In some examples, the visualization system 710 can include two screens 732, such that the modulated light from each screen 732 can be directed toward a respective eye of the user. In some examples, the visualization system 710 can include more than two screens 732. In a second configuration, the visualization system 710 can direct the modulated light directly into one or both eyes of a viewer. For example, the projection optics 730 can form an image on a retina of an eye of the user, or an image on each retina of the two eyes of the user.

For some configurations of AR systems, the visualization system 710 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

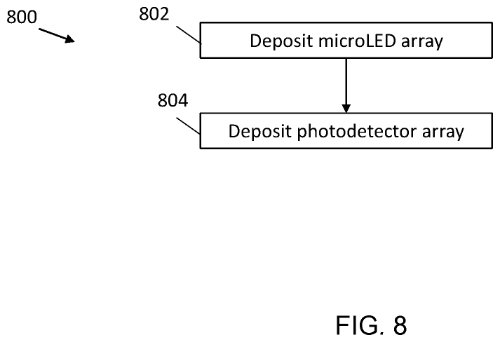

FIG. 8 show an example method of forming a display, in accordance with some embodiments. The method 800 may be performed in an order different from that shown. Other operations may be used, but are not shown for convenience. At operation 802, a microLED array may be deposited on a backplane. The backplane may be a CMOS backplane or a transparent backplane, depending on the application. At operation 804, a photodetector array may be deposited on the backplane. The photodetectors of the photodetector array may be interspersed with microLEDs of the microLED array. The photodetectors may be disposed between adjacent microLEDs or between sets (e.g., pairs) of adjacent microLEDs. The spacing of the photodetectors may be uniform throughout the backplane or may be non-uniform (e.g., a larger number of photodetectors may be used in an area of the backplane that is more likely to be viewed/in which eye tracking is more likely—such as a center of the backplane—than another area—such as the edges of the backplane). The photodetectors may have a metasurface formed from a grating having one or more spacings. The metasurface has a narrow acceptance angular range and whose orientation is the same throughout the backplane or whose orientations are different (e.g., random). One or more insulating layers whose dielectric constants are changeable through external stimulus (e.g., electrical, thermal) may be incorporated in the photodetectors to change the center of the angular range and thus relative angle of acceptance.

Operations 802 and/or 804 may be repeated, placing the microLEDs and photodetectors in sets using a mass transfer process. In some embodiments, each set of microLEDs may be deposited on the backplane prior to the sets of photodetectors being deposited on the backplane; or alternatively, the sets of photodetectors are deposited prior to the sets of microLEDs. In other embodiments, one or more sets of photodetectors are deposited between one or more sets of microLEDs. After depositing the devices on the backplane, the devices may be attached to the backplane either after each placement or after all of the devices have been placed on the backplane.

### EXAMPLES

Example 1 is a light emitting diode (LED) device comprising: a backplane; a microLED array disposed on the backplane and that contains microLED pixels, each microLED pixel containing microLEDs configured to emit light of at least one wavelength; and a photodetector array that contains photodetector pixels interspersed with the microLED pixels on the backplane, each photodetector pixel containing a metasurface and a photodetector, the metasurface configured to accept the light of the at least one wavelength that impinges on the metasurface with a narrow angular range, the photodetector configured to generate current based on the light.

In Example 2, the subject matter of Example 1 includes, wherein the metasurface of each photodetector pixel contains a grating that provides filtering of the light, insulating spacers, and a conductive waveguide layer disposed on a substrate and between the insulating spacers, the insulating spacers having a refractive index to permit coupling to the waveguide layer, the waveguide layer configured to guide light in the waveguide layer to an active region of the photodetector where current is generated by the light guided by the conductive waveguide layer.

In Example 3, the subject matter of Example 2 includes, wherein at least one of the insulating spacers is formed from a material whose refractive index changes with at least one of an applied electrical or thermal stimulus to control a direction of a center angle of the narrow angular range of the photodetector pixel.

In Example 4, the subject matter of Examples 2-3 includes, wherein each photodetector pixel further contains a thermally or electrooptically sensitive material whose refractive index changes with at least one of an applied electrical or thermal stimulus to control a direction of a center angle of the narrow angular range of the photodetector pixel.

In Example 5, the subject matter of Examples 1-4 includes, wherein the microLED pixels are configured to emit near infrared light and the photodetector pixels are configured to receive the near infrared light.

In Example 6, the subject matter of Examples 1-5 includes, wherein each photodetector pixel is configured to detect light having a specific set of parameters that include polarization, color, and angular range.

In Example 7, the subject matter of Examples 1-6 includes, wherein each photodetector pixel is disposed between adjacent microLED pixels and each microLED pixel is disposed between adjacent photodetector pixels such that a number of photodetector pixels corresponds to an equal number of microLED pixels.

In Example 8, the subject matter of Examples 1-7 includes, wherein each photodetector pixel is disposed between adjacent sets of microLED pixels in at least one direction, each set of microLED pixels including a plurality of adjacent microLED pixels.

In Example 9, the subject matter of Examples 1-8 includes, wherein at least some of the photodetector pixels have different orientations.

In Example 10, the subject matter of Examples 1-9 includes, wherein the photodetector pixels have identical orientations.

In Example 11, the subject matter of Examples 1-10 includes, wherein each microLED pixel includes a red microLED, a green microLED, and a blue microLED, and each photodetector pixel has at least one color filter disposed on a top surface of the metasurface.

In Example 12, the subject matter of Examples 1-11 includes, wherein the backplane is formed from a material that is substantially transparent to light of visible wavelengths and the microLED array and the photodetector array are sparse arrays.

Example 13 is a light emitting diode (LED) display comprising: a backplane; a microLED array disposed on the backplane and that contains microLED pixels, each microLED pixel containing microLEDs configured to emit light of at least one wavelength; a photodetector array that contains photodetector pixels disposed on the backplane, each photodetector pixel containing a metasurface and a photodetector, the metasurface configured to accept the light of the at least one wavelength that impinges on the metasurface with a narrow angular range, the photodetector configured to generate current based on the light; and a processor configured to control the microLED array based on signals from the photodetector array.

In Example 14, the subject matter of Example 13 includes, a viewing area and a frame that surrounds the viewing area contains the backplane, the backplane being a complementary metal oxide semiconductor (CMOS) backplane.

In Example 15, the subject matter of Examples 13-14 includes, wherein the metasurface of each photodetector pixel contains a grating that provides filtering of the light, insulating spacers, and a conductive waveguide layer disposed on a substrate and between the insulating spacers, the insulating spacers having a refractive index to permit coupling to the waveguide layer, the waveguide layer configured to support surface plasmons and act as a waveguide for in-plane light.

In Example 16, the subject matter of Example 15 includes, wherein at least one of the insulating spacers is formed from a material whose refractive index changes with at least one of an applied electrical or thermal stimulus to control a direction of a center angle of the narrow angular range of the photodetector pixel.

In Example 17, the subject matter of Examples 15-16 includes, wherein the backplane is formed from a material that is substantially transparent to light of visible wavelengths and the microLED array and the photodetector array are sparse arrays.

In Example 18, the subject matter of Examples 15-17 includes, wherein each photodetector pixel is configured to detect light having a specific set of parameters that include polarization, color, and angular range.

Example 19 is a method of forming a micro light emitting diode (LED) device, the method comprising: depositing one or more sets of microLEDs on a backplane to form a microLED array; and depositing one or more sets of photodetector pixels on the backplane to form a photodetector array, at least some of the photodetector pixels interspersed with the microLEDs, each photodetector pixel containing a metasurface and a photodetector, the metasurface configured to accept light of at least one wavelength that impinges on the metasurface with a narrow angular range, the photodetector configured to generate current based on the light.

In Example 20, the subject matter of Example 19 includes, wherein: the metasurface of each photodetector pixel contains a grating that provides filtering of the light, insulating spacers, and a conductive waveguide layer disposed on a substrate and between the insulating spacers, the insulating spacers having a refractive index to permit coupling to the waveguide layer, the waveguide layer configured to support surface plasmons and act as a waveguide for in-plane light; and at least one of the insulating spacers is formed from a material whose refractive index changes with at least one of an applied electrical or thermal stimulus to control a direction of a center angle of the narrow angular range of the photodetector pixel.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to indicate one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. As indicated herein, although the term “a” is used herein, one or more of the associated elements may be used in different embodiments. For example, the term “a processor” configured to carry out specific operations includes both a single processor configured to carry out all of the operations as well as multiple processors individually configured to carry out some or all of the operations (which may overlap) such that the combination of processors carry out all of the operations. Further, the term “includes” may be considered to be interpreted as “includes at least” the elements that follow.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A light emitting diode (LED) device comprising:
a backplane;
a microLED array disposed on the backplane and that contains microLED pixels, each microLED pixel containing microLEDs configured to emit light of at least one wavelength; and
a photodetector array that contains photodetector pixels interspersed with the microLED pixels on the backplane, each photodetector pixel containing a metasurface and a photodetector, the metasurface configured to accept the light of the at least one wavelength that impinges on the metasurface with a narrow angular range, the photodetector configured to generate current based on the light.

2. The LED device of claim 1, wherein the metasurface of each photodetector pixel contains a grating that provides filtering of the light, insulating spacers, and a conductive waveguide layer disposed on a substrate and between the insulating spacers, the insulating spacers having a refractive index to permit coupling to the waveguide layer, the waveguide layer configured to guide light in the waveguide layer to an active region of the photodetector where current is generated by the light guided by the conductive waveguide layer.

3. The LED device of claim 2, wherein at least one of the insulating spacers is formed from a material whose refractive index changes with at least one of an applied electrical or thermal stimulus to control a direction of a center angle of the narrow angular range of the photodetector pixel.

4. The LED device of claim 2, wherein each photodetector pixel further contains a thermally or electrooptically sensitive material whose refractive index changes with at least one of an applied electrical or thermal stimulus to control a direction of a center angle of the narrow angular range of the photodetector pixel.

5. The LED device of claim 1, wherein the microLED pixels are configured to emit near infrared light and the photodetector pixels are configured to receive the near infrared light.

6. The LED device of claim 1, wherein each photodetector pixel is configured to detect light having a specific set of parameters that include polarization, color, and angular range.

7. The LED device of claim 1, wherein each photodetector pixel is disposed between adjacent microLED pixels and each microLED pixel is disposed between adjacent photodetector pixels such that a number of photodetector pixels corresponds to an equal number of microLED pixels.

8. The LED device of claim 1, wherein each photodetector pixel is disposed between adjacent sets of microLED pixels in at least one direction, each set of microLED pixels including a plurality of adjacent microLED pixels.

9. The LED device of claim 1, wherein at least some of the photodetector pixels have different orientations.

10. The LED device of claim 1, wherein the photodetector pixels have identical orientations.

11. The LED device of claim 1, wherein each microLED pixel includes a red microLED, a green microLED, and a blue microLED, and each photodetector pixel has at least one color filter disposed on a top surface of the metasurface.

12. The LED device of claim 1, wherein the backplane is formed from a material that is substantially transparent to light of visible wavelengths and the microLED array and the photodetector array are sparse arrays.

13. A light emitting diode (LED) display comprising:
a backplane;
a microLED array disposed on the backplane and that contains microLED pixels, each microLED pixel containing microLEDs configured to emit light of at least one wavelength;
a photodetector array that contains photodetector pixels disposed on the backplane, each photodetector pixel containing a metasurface and a photodetector, the metasurface configured to accept the light of the at least one wavelength that impinges on the metasurface with a narrow angular range, the photodetector configured to generate current based on the light; and
a processor configured to control the microLED array based on signals from the photodetector array.

14. The LED display of claim 13, further comprising a viewing area and a frame that surrounds the viewing area contains the backplane, the backplane being a complementary metal oxide semiconductor (CMOS) backplane.

15. The LED display of claim 13, wherein the metasurface of each photodetector pixel contains a grating that provides filtering of the light, insulating spacers, and a conductive waveguide layer disposed on a substrate and between the insulating spacers, the insulating spacers having a refractive index to permit coupling to the waveguide layer, the waveguide layer configured to support surface plasmons and act as a waveguide for in-plane light.

16. The LED display of claim 15, wherein at least one of the insulating spacers is formed from a material whose refractive index changes with at least one of an applied electrical or thermal stimulus to control a direction of a center angle of the narrow angular range of the photodetector pixel.

17. The LED display of claim 15, wherein the backplane is formed from a material that is substantially transparent to light of visible wavelengths and the microLED array and the photodetector array are sparse arrays.

18. The LED display of claim 15, wherein each photodetector pixel is configured to detect light having a specific set of parameters that include polarization, color, and angular range.

19. A method of forming a micro light emitting diode (LED) device, the method comprising:
depositing one or more sets of microLEDs on a backplane to form a microLED array; and
depositing one or more sets of photodetector pixels on the backplane to form a photodetector array, at least some of the photodetector pixels interspersed with the microLEDs, each photodetector pixel containing a metasurface and a photodetector, the metasurface configured to accept light of at least one wavelength that impinges on the metasurface with a narrow angular range, the photodetector configured to generate current based on the light.

20. The method of claim 19, wherein:
the metasurface of each photodetector pixel contains a grating that provides filtering of the light, insulating spacers, and a conductive waveguide layer disposed on a substrate and between the insulating spacers, the insulating spacers having a refractive index to permit coupling to the waveguide layer, the waveguide layer configured to support surface plasmons and act as a waveguide for in-plane light; and
at least one of the insulating spacers is formed from a material whose refractive index changes with at least one of an applied electrical or thermal stimulus to control a direction of a center angle of the narrow angular range of the photodetector pixel.
